(19) United States
(12) Patent Application Publication
(10) Pub. No.: US 2024/0024927 A1
(43) Pub. Date: Jan. 25, 2024

(54) SPINNER UNIT

(71) Applicant: DISCO CORPORATION, Tokyo (JP)

(72) Inventors: Tomoaki ENDO, Tokyo (JP); Hiroto YOSHIDA, Tokyo (JP)

(21) Appl. No.: 18/348,463

(22) Filed: Jul. 7, 2023

(30) Foreign Application Priority Data
Jul. 22, 2022 (JP) 2022-116913

(51) Int. Cl. B08B 3/04; B08B 13/00

(52) U.S. Cl. CPC B08B 3/041; B08B 13/00

(57) ABSTRACT

A spinner unit is provided with a spinner table which holds a plate-shaped workpiece and rotates, a liquid supply nozzle which supplies liquid to the plate-shaped workpiece held on the spinner table, an accommodation chamber which accommodates the spinner table, and a waste fluid path which is communicated with the accommodation chamber. The spinner unit includes a separator which is disposed below an upper surface of the spinner table in the accommodation chamber so as to divide the accommodation chamber into an upper space and a lower space, the lower space being communicated with the waste fluid path, and which partially closes between the upper space and the lower space. The spinner unit has gaps each serving as a path through which the liquid advances from the upper space to the lower space in the separator or in a periphery of the separator.

### BACKGROUND OF THE INVENTION

### Field of the Invention

The present invention relates to a spinner unit including a spinner table for holding a plate-shaped workpiece such as a semiconductor wafer and rotating, a supply nozzle which supplies liquid to the plate-shaped workpiece held on the spinner table, and an accommodation chamber which accommodates the spinner table.

### Description of the Related Art

A technique of manufacturing device chips by setting a plurality of dividing lines crossing each other on a front surface of a plate-shaped workpiece such as a wafer, forming devices in individual separate regions demarcated by the plurality of dividing lines, and dividing the plate-shaped workpiece along the dividing lines into individual pieces has been known. In addition, prior to dividing of the plate-shaped workpiece, such a technique that the plate-shaped workpiece is worn from a back surface side thereof to be thinned has been known. For division of the plate-shaped workpiece, a cutting apparatus provided with an annular shaped cutting blade, a laser processing apparatus which applies a laser beam to the plate-shaped workpiece to perform laser processing, or the like, is used. In addition, for thinning the plate-shaped workpiece, a grinding apparatus including a grinding wheel having grinding stones arranged in an annular shape, and a polishing apparatus which polishes a ground surface of the plate-shaped workpiece to flatten are used. These processing apparatuses incorporate a spinner cleaning unit to clean a processed workpiece.

A spinner cleaning unit which cleans a plate-shaped workpiece includes a spinner table which holds the plate-shaped workpiece and rotates, a supply nozzle which supplies cleaning water as liquid to the plate-shaped workpiece held on the spinner table, and an accommodation chamber which accommodates the spinner table. When the cleaning water is jetted from the supply nozzle to a front surface of the plate-shaped workpiece while rotating the spinner table holding the plate-shaped workpiece, the plate-shaped workpiece can be cleaned (for example, see Japanese Patent Laid-Open No. 2006-128359).

In addition, a spin coater which applies liquid resin to a front surface of a plate-shaped workpiece uniformly to provide a resin film thereon has been known. As in the spinner cleaning unit described above, the spin coater includes a spinner table which holds the plate-shaped workpiece and rotates, a supply nozzle which supplies liquid resin as liquid to the plate-shaped workpiece held on the spinner table, and an accommodation chamber which accommodates the spinner table. When the liquid resin is discharged from the supply nozzle to the front surface of the plate-shaped workpiece while rotating the spinner table holding the plate-shaped workpiece and then the liquid resin is dried, a resin film having a predetermined thickness is provided on the front surface of the plate-shaped workpiece. The spin coater may be used in a manner to be incorporated in the laser processing apparatus, in some cases. Liquid resin containing water-soluble resin is applied to the front surface of the plate-shaped workpiece by the spin coater and dried, to thereby form a water-soluble resin film. Thereafter, a laser beam is applied to the plate-shaped workpiece through the water-soluble resin film to perform laser processing. As a result, scattering debris attributable to this processing adheres onto the water-soluble resin film. Subsequently, when the plate-shaped workpiece is cleaned to remove the water-soluble resin film, the scattering debris is removed as well, and consequently, no scattering debris remains on the front surface of the plate-shaped workpiece (see Japanese Patent Laid-Open No. 2004-322168).

In such a spinner unit including the spinner table as the spinner cleaning unit or the spin coater, the liquid supplied to the plate-shaped workpiece drops from the plate-shaped workpiece to a bottom plate of the accommodation chamber. Then, the liquid is discharged as waste fluid from a waste fluid path connected to the bottom plate.

### SUMMARY OF THE INVENTION

However, part of the liquid dropping from the plate-shaped workpiece in the spinner unit may not reach the waste fluid path and may remain on the bottom plate or an inner wall of the accommodation chamber, in some cases. When the spinner table is rotated at high speed in this state to supply the liquid to a next plate-shaped workpiece, air in the accommodation chamber is entrained to generate air flow in the accommodation chamber, and the liquid remaining in the accommodation chamber is entrained into this air flow. Then, the entrained liquid scatters to the front surface of the plate-shaped workpiece held on the spinner table or leaks outside the accommodation chamber, resulting in a contamination source, which is problematic.

Accordingly, it is an object of the present invention to provide a spinner unit in which entrainment of liquid remaining in the accommodation chamber in association with rotation of the spinner table is reduced.

In accordance with an aspect of the present invention, there is provided a spinner unit provided with a spinner table which holds a plate-shaped workpiece and rotates, a liquid supply nozzle which supplies liquid to the plate-shaped workpiece held on the spinner table, an accommodation chamber which accommodates the spinner table, and a waste fluid path which is communicated with the accommodation chamber, the spinner unit including a separator which is disposed below an upper surface of the spinner table in the accommodation chamber so as to divide the accommodation chamber into an upper space and a lower space, the lower space being communicated with the waste fluid path, and which partially closes between the upper space and the lower space. The spinner unit has gaps each serving as a path through which the liquid advances from the upper space to the lower space in the separator or in a periphery of the separator.

Preferably, the separator has a plurality of through holes constituting the gaps, and causes the received liquid to flow down from the through holes to the lower space of the accommodation chamber.

In addition, preferably, an upper surface of the separator is inclined so as to cause the received liquid to flow down toward the gaps.

In addition, preferably, the separator includes a plurality of plate-like portions each being inclined downward along a rotational direction of the spinner table, each of the gaps is positioned between two adjacent ones of the plate-like portions, and air flow generated by rotation of the spinner table sweeps away the liquid received by the plurality of plate-like portions on an upper surface of each plate-like portion, to cause the liquid to flow down to the lower space of the accommodation chamber.

The spinner unit according to the aspect of the present invention includes the separator which is disposed in the accommodation chamber so as to divide the accommodation chamber that accommodates the spinner table into the upper space and the lower space. Also, this spinner unit has the gaps in the separator or in the periphery of the separator. This gap serves as the path through which the liquid advances from the upper space to the lower space. In this case, when the liquid supplied to the plate-shaped workpiece held on the spinner table drops outside the spinner table, the liquid passes through the gap and advances to the lower space of the accommodation chamber, to thereby be discharged from the waste fluid path. Meanwhile, advancement of air flow generated in association with rotation of the spinner table is disturbed by the separator, making it difficult for the air flow to move beyond the separator. Hence, momentum of the air flow reaching the lower space of the accommodation chamber is weakened by the separator, and entrainment of the liquid remaining in the lower space of the accommodation chamber by the air flow is thereby reduced. Moreover, advancement of the liquid entrained in the lower space of the accommodation chamber is also disturbed by the separator, so that the liquid passing through the gap to the upper space becomes extremely less.

Hence, according to the aspect of the present invention, a spinner unit which reduces entrainment of the liquid remaining in the accommodation chamber in association with rotation of the spinner table is provided.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a laser processing apparatus;

FIG. 2 is a perspective view schematically illustrating a spinner unit according to a preferred embodiment of the present invention;

FIG. 3 is a cross-sectional view schematically illustrating the spinner unit of FIG. 2;

FIG. 4 is a perspective view schematically illustrating a spinner unit according to a modification example of the embodiment of the present invention;

FIG. 5 is a cross-sectional view schematically illustrating the spinner unit of FIG. 4;

FIG. 6A is a perspective view schematically illustrating a separator according to a modification example;

FIG. 6B is a perspective view schematically illustrating a separator according to another modification example;

FIG. 7 is a perspective view schematically illustrating a separator according to still another modification example;

FIG. 8A is a perspective view schematically illustrating a separator that is dividable into three separated parts according to yet another modification example;

FIG. 8B is a perspective view schematically illustrating one separated part included in the separator of FIG. 8A; and

FIG. 9 is a perspective view schematically illustrating a separator according to a further modification example.

### DETAILED DESCRIPTION OF THE PREFERRED EMBODIMENT

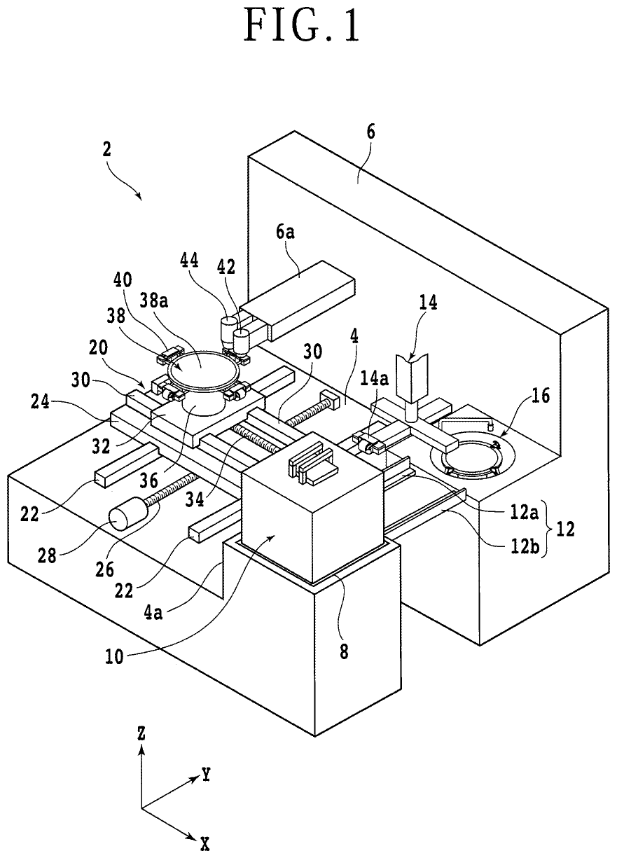

Hereinafter, an embodiment according to an aspect of the present invention will be described with reference to the accompanying drawings. A spinner unit according to the present embodiment is used being incorporated in a processing apparatus such as a laser processing apparatus indicated in FIG. 1, for example. The laser processing apparatus applies a laser beam to a plate-shaped workpiece to process the plate-shaped workpiece. In the laser processing apparatus, for example, a spinner unit supplies a front surface of the plate-shaped workpiece with liquid resin to form a water-soluble resin film on the front surface of the plate-shaped workpiece, the plate-shaped workpiece is processed by a laser beam, and the spinner unit further supplies the plate-shaped workpiece with cleaning water to clean the plate-shaped workpiece. First, the plate-shaped workpiece will be described.

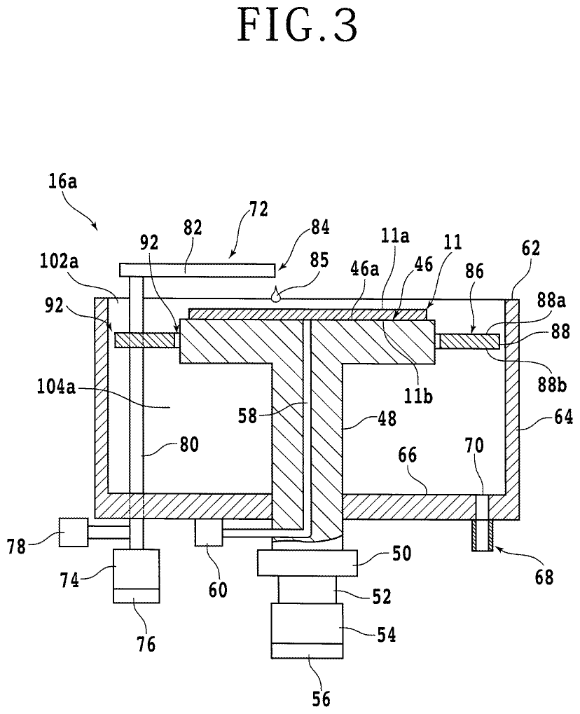

FIG. 3 includes a cross-sectional view schematically illustrating a plate-shaped workpiece 11. The plate-shaped workpiece 11 is, for example, a disc-shaped wafer formed of a semiconductor material such as silicon. The plate-shaped workpiece 11 has, on a front surface 11a thereof, a plurality of dividing lines set thereon, the dividing lines crossing each other. Each of regions demarcated by the dividing lines in a grid manner has a device such as an integrated circuit (IC) or a large scale integration (LSI) formed therein. It is to be noted that, however, the plate-shaped workpiece 11 is not limited in material, shape, structure, size, etc., and the devices are not limited in kind, number, shape, structure, size, layout, etc. When the plate-shaped workpiece 11 is processed by a processing apparatus, a wafer unit including the plate-shaped workpiece, a dicing tape, and an annular frame may be formed. The dicing tape is a circular tape larger in diameter than the wafer. The plate-shaped workpiece 11 is attached to a center portion of the dicing tape, and the annular frame made of metal is attached to an outer peripheral portion of the dicing tape. Thus, a wafer unit in which the plate-shaped workpiece 11 is supported by the annular frame through the dicing tape is formed. Alternatively, the wafer unit may not be formed.

The plate-shaped workpiece 11 is transported to a laser processing apparatus to be processed. FIG. 1 is a perspective view schematically illustrating a laser processing apparatus 2. Note that, in the following description, an X-axis direction (processing feed direction), a Y-axis direction (indexing feed direction), and a Z-axis direction (vertical direction, or a height direction) are perpendicular to each other. The laser processing apparatus 2 includes a base 4 which supports each structure. At a corner portion of the base 4, a protruding section 4a is provided in such a manner as to protrude in the Z-axis direction. The protruding section 4a has a space formed inside thereof, and in this space, a cassette elevator 8 that is vertically movable along the Z-axis direction is provided. A cassette 10 is placed on an upper surface of the cassette elevator 8, and the cassette 10 houses a plurality of the plate-shaped workpieces 11.

A temporary rest mechanism 12 for temporarily placing the plate-shaped workpiece 11 (wafer unit) is provided on one side of the protruding section 4a in the Y-axis direction. The temporary rest mechanism 12 includes a pair of guide rails 12a and 12b that move toward or away from each other, keeping a state parallel to the Y-axis direction. The temporary rest mechanism 12 causes the guide rails 12a and 12b to come into abutment against the outer circumference of the plate-shaped workpiece 11 therebetween in the X-axis direction, to adjust a position of the plate-shaped workpiece 11 in the X-axis direction to a predetermined position. Above the temporary rest mechanism 12, there is provided a transport mechanism 14 which transports the plate-shaped workpiece 11. The transport mechanism 14 has a grip portion 14a for gripping part of the frame. The transport mechanism 14 draws the plate-shaped workpiece 11 from the cassette 10 to the temporary rest mechanism 12 in a state in which the frame is gripped with the grip portion 14a. The transport mechanism 14 has suction mechanisms (not depicted) provided on bottom portions thereof, the suction mechanisms sucking multiple portions of the frame to hold the frame. The plate-shaped workpiece 11 held under suction by the suction mechanisms is transported to a coating cleaner unit 16 or a chuck table 38 which will be described later, by the transport mechanism 14.

On one side of the temporary rest mechanism 12 in the Y-axis direction, there is provided a coating cleaner unit 16 that is the spinner unit according to the present embodiment. In the coating cleaner unit 16, liquid resin is supplied to the plate-shaped workpiece 11 to form a water-soluble resin film. In addition, in the coating cleaner unit 16, cleaning water is supplied to a laser-processed plate-shaped workpiece 11 to clean the plate-shaped workpiece 11. The coating cleaner unit 16 can function as a spin coater and as a spinner cleaning unit. A detailed description of the coating cleaner unit 16 will be given later.

A horizontal moving mechanism 20 is provided on a front surface (upper surface) of the base 4 positioned on one side of the X-axis direction with respect to the coating cleaner unit 16. The horizontal moving mechanism 20 includes a pair of Y-axis guide rails 22 fixed to the upper surface of the base 4 and parallel to the Y-axis direction. The Y-axis guide rails 22 has a Y-axis moving table 24 slidably attached thereto. A nut (not depicted) is provided on a back surface side (lower surface side) of the Y-axis moving table 24, and a Y-axis ball screw 26 parallel to the Y-axis guide rails 22 is screwed into this nut in a rotatable manner. A Y-axis pulse motor 28 is coupled with one end portion of the Y-axis ball screw 26. When the Y-axis pulse motor 28 rotates the Y-axis ball screw 26, the Y-axis moving table 24 moves along the Y-axis guide rails 22 in the Y-axis direction. A pair of X-axis guide rails 30 parallel to the X-axis direction are provided on a front surface (upper surface) of the Y-axis moving table 24.

The X-axis guide rails 30 has an X-axis moving table 32 slidably attached thereto. A nut (not depicted) is provided on a back surface side (lower surface side) of the X-axis moving table 32, and an X-axis ball screw 34 parallel to the X-axis guide rails 30 is screwed into this nut in a rotatable manner. An X-axis pulse motor (not depicted) is coupled with one end portion of the X-axis ball screw 34. When the X-axis pulse motor rotates the X-axis ball screw 34, the X-axis moving table 32 moves along the X-axis guide rails 30 in the X-axis direction.

There is provided a table base 36 on a front surface side (upper surface side) of the X-axis moving table 32. At an upper portion of the table base 36, a chuck table 38 for holding under suction the plate-shaped workpiece 11 (wafer unit) is provided. In the periphery of the chuck table 38, four clamps 40 which fix the frame included in the wafer unit at four corresponding portions of the frame may be provided. A bottom portion of the chuck table 38 is coupled with a rotational drive source (not depicted) of a motor or the like provided in the table base 36, so as to be rotatable around a rotary axis parallel to the Z-axis direction. An upper surface of the chuck table 38 is a holding surface 38a for holding under suction the plate-shaped workpiece 11. The holding surface 38a is connected to a suction source (not depicted) such as an ejector through a suction passage (not depicted) or the like which is formed in the chuck table 38 or the table base 36. When the suction source is operated, a negative pressure is generated and exerted on the holding surface 38a.

On one end portion of the base 4 in the Y-axis direction, a wall-like support structure 6 extending along the Z-axis direction is provided. The support structure 6 has a support arm 6a protruding toward a center of the base 4 provided thereto. At a distal end portion of this support arm 6a, a light condenser 42 which applies a laser beam downward is provided. The light condenser 42 has a laser oscillator (not depicted) optically connected thereto, the laser oscillator generating a pulsed laser beam. The light condenser 42, the laser oscillator, and the like constitute a laser beam applying unit. The laser beam applied from the light condenser 42 has a wavelength absorbable by the plate-shaped workpiece 11. The wavelength of the laser beam is a wavelength of an ultraviolet region (for example, 355 nm). In addition, an average power of the laser beam is adjusted to, for example, 0.5 W, and a repetitive frequency of the pulse of the laser beam is adjusted to, for example, 200 kHz.

An imaging head 44 of a camera unit for imaging the plate-shaped workpiece 11 is provided at a position adjacent to the light condenser 42. This camera unit is a visible light camera unit (not depicted) or an infrared (IR) camera unit (not depicted) and is used for alignment of the plate-shaped workpiece 11 or a kerf inspection, for example. The camera unit has, for example, an imaging element (not depicted) such as a complementary metal oxide semiconductor (CMOS) image sensor or a charge coupled device (CCD) image sensor.

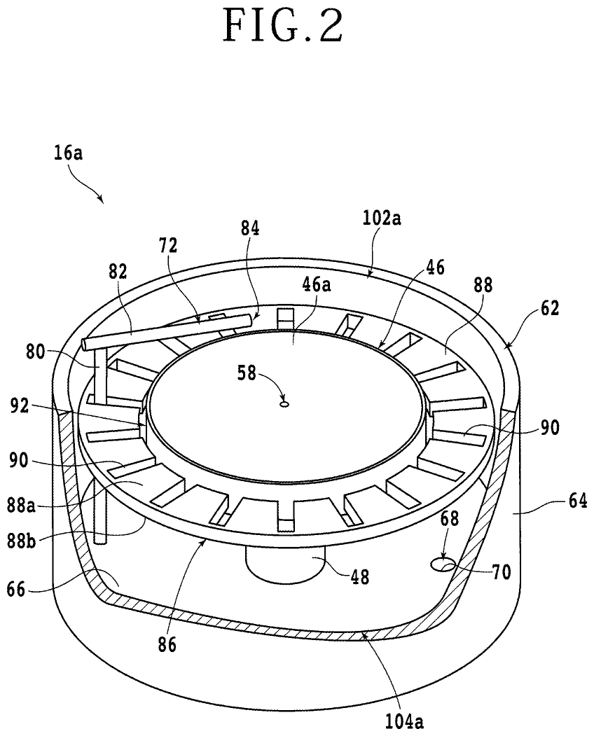

A coating cleaner unit 16 that is the spinner unit according to the present embodiment will be described. FIG. 2 is a perspective view schematically illustrating a coating cleaner unit (spinner unit) 16a according to an example of the present embodiment, and FIG. 3 is a cross-sectional view schematically illustrating the coating cleaner unit 16a of FIG. 2. The coating cleaner unit 16a has a cylindrical space inside, and in this cylindrical space, there is provided a spinner table 46 rotatable in a state in which the plate-shaped workpiece 11 is held under suction thereon. This internal space in which the spinner table 46 is accommodated is surrounded by a cylindrical side wall 64 and a bottom plate 66. In other words, the coating cleaner unit (spinner unit) 16a includes an accommodation chamber 62 for accommodating the spinner table 46. The accommodation chamber 62 includes the side wall 64 and the bottom plate 66 which are formed of stainless steel or the like. Note that an upper side of the internal space of the spinner table 46 may be closed by an unillustrated lid member freely openable and closable.

The spinner table 46 is connected to an upper end of a table rotary axis 48, and a lower end of the table rotary axis 48 protrudes downward, penetrating the bottom plate 66, and is connected to a rotational mechanism. The rotational mechanism includes a motor 54, a rotary shaft 52 of the motor 54, and a rotary joint 50 connecting the rotary shaft 52 and the table rotary axis 48. In addition, the motor 54 has an encoder 56 built therein, the encoder 56 being used for control of a rotational speed or the like. The table rotary axis 48 transmits a rotational force generated by the motor 54 to the spinner table 46.

An upper surface of the spinner table 46 serves as a holding surface 46a for holding under suction the plate-shaped workpiece 11. The holding surface 46a may have a porous member disposed thereon. Inside the spinner table 46 and the table rotary axis 48, a suction passage 58 is formed such that one end thereof is connected to a suction source 60 such as a pump and the other end thereof is connected to the holding surface 46a. Here, for convenience of description, a connection mechanism maintaining connection between the holding surface 46a and the suction source 60 even during rotation of the spinner table 46 is omitted in FIG. 3. When the plate-shaped workpiece 11 is placed on the holding surface 46a of the spinner table 46 and the suction source 60 is operated to apply a negative pressure to the plate-shaped workpiece 11 through the suction passage 58, the plate-shaped workpiece 11 is held under suction on the spinner table 46.

Clamps (not depicted) which hold the frame of the wafer unit including the plate-shaped workpiece 11 may be disposed on an outer peripheral side of an upper side of the spinner table 46. Each clamp has a lower weight portion and an upper grip portion and is rotatable around a shaft provided between the weight portion and the grip portion. For example, a centrifugal force attributable to rotation of the spinner table 46 causes the lower weight portion to move toward the outer peripheral side of the spinner table 46, so that the upper grip portion automatically falls down on the inner peripheral side of the spinner table 46 to clamp the frame. It is to be noted that, however, the spinner table 46 may not have any clamps.

A waste fluid port 70 is provided in the bottom plate 66 of the accommodation chamber 62, and this waste fluid port 70 has a waste fluid path 68 connected thereto, the waste fluid path 68 including a tube or the like. Specifically, the coating cleaner unit (spinner unit) 16a has the waste fluid path 68 being communicated with the accommodation chamber 62. The waste fluid path 68 is communicated with a waste fluid tank or a waste fluid processing facility. Liquid 85 supplied to the plate-shaped workpiece 11 held on the spinner table 46 drops on the bottom plate 66 of the accommodation chamber 62 and then moves from the waste fluid port 70 to the waste fluid path 68, to thereby be discharged from the coating cleaner unit (spinner unit) 16a.

The coating cleaner unit (spinner unit) 16a includes a liquid supply nozzle 72 supplying the liquid 85 to the plate-shaped workpiece 11 held on the spinner table 46. At an outer peripheral portion of the bottom plate 66, a pipe-like shaft portion 80 of the liquid supply nozzle 72 is provided in such a manner penetrating the bottom plate 66. The shaft portion 80 is a pipe-like member extending along a direction vertical to the holding surface 46a outside the spinner table 46, reaches a position higher than the height of the holding surface 46a, and has an arm portion 82 connected to an upper end thereof. A motor 74 which rotates the shaft portion 80 is connected to a proximal end side of the shaft portion 80, and the shaft portion 80 is rotated by the motor 74 around an axis vertical to the holding surface 46a. The motor 74 has an encoder 76 built therein, the encoder 76 being used for control of a rotational angle of the shaft portion 80.

In addition, a liquid supply source 78 which supplies the liquid 85 to the liquid supply nozzle 72 is connected on the proximal end side of the shaft portion 80. The liquid supply source 78 supplies, for example, liquid resin that is a material of the water-soluble resin film to the liquid supply nozzle 72. As the liquid resin, for example, PVA (polyvinyl alcohol), PEG (polyethylene glycol), PEO (oxidized polyethylene), and the like are used. Alternatively, the liquid supply source 78 supplies deionized water functioning as cleaning water to the liquid supply nozzle 72. Moreover, the liquid supply source 78 may mix high pressure air into the cleaning water in order to strongly clean the plate-shaped workpiece 11 to supply the resultant fluid to the liquid supply nozzle 72. Specifically, the coating cleaner unit (spinner unit) 16a may perform cleaning by the mixed fluid of the deionized water and the high pressure air on the plate-shaped workpiece 11. Note that the liquid 85 supplied by the liquid supply source 78 is not limited to them.

The arm portion 82 connected to the upper end of the shaft portion 80 is a pipe-like member having a length corresponding to a distance from the shaft portion 80 to the center of the holding surface 46a of the spinner table 46 and extending in a direction vertical to the extending direction of the shaft portion 80. A discharge port 84 which orients downward is provided at a distal end of the arm portion 82.

When the coating cleaner unit (spinner unit) 16a supplies the plate-shaped workpiece 11 with liquid, the plate-shaped workpiece 11 is held under suction on the spinner table 46. At this time, the front surface 11a of the plate-shaped workpiece 11 that is to be supplied with liquid is exposed upward, so that a back surface 11b of the plate-shaped workpiece 11 is made to face the holding surface 46a of the spinner table 46. Thereafter, the spinner table 46 is rotated at high speed, and the shaft portion 80 is rotated around its axis, thereby causing the arm portion 82 of the liquid supply nozzle 72 to reciprocate above the spinner table 46. Then, the liquid is discharged from the discharge port 84 of the liquid supply nozzle 72 toward the plate-shaped workpiece 11. Consequently, the liquid 85 is supplied to the plate-shaped workpiece 11. When the liquid resin as the liquid is supplied to the plate-shaped workpiece 11 and dried, a water-soluble resin film can be formed on the plate-shaped workpiece 11. In addition, when deionized water into which high pressure air is mixed is supplied as the liquid 85 to the plate-shaped workpiece 11, the plate-shaped workpiece 11 can be cleaned. Part or all of the liquid 85 supplied to the plate-shaped workpiece 11 falls off from the plate-shaped workpiece 11 and then drops onto the bottom plate 66 of the accommodation chamber 62 outside the spinner table 46, then moves from the waste fluid port 70 to the waste fluid path 68, and is thereafter discharged outside the accommodation chamber 62.

Here, the part of the liquid 85 dropping from the plate-shaped workpiece 11 may not reach the waste fluid path 68 and may remain on the bottom plate 66 of the accommodation chamber 62. In addition, the part of the liquid 85 may scatter inside the accommodation chamber 62 and adhere to an inner surface of the side wall 64. Moreover, dust or the like contained in the liquid 85 may adhere to the inner surface of the accommodation chamber 62. Then, in a case in which the spinner table 46 is rotated at high speed when the liquid 85 is supplied to a next plate-shaped workpiece 11, air in the accommodation chamber 62 is entrained, and accordingly, air flow is generated in the accommodation chamber 62. This air flow flows in the accommodation chamber 62 in such a manner as to swirl with the spinner table 46 as a center, thereby causing the liquid 85 and the like remaining in the accommodation chamber 62 to be entrained.

The liquid 85 and the like being entrained by the air flow may scatter onto the front surface 11a of the plate-shaped workpiece 11. In this case, the scattering liquid 85 and the like contaminates the plate-shaped workpiece 11, causing difficulty in following steps of processing on the plate-shaped workpiece 11 and reduction in quality of chips formed by dividing the plate-shaped workpiece 11. In addition, the liquid 85 and the like being entrained by the air flow may leak outside from the accommodation chamber 62 to be a contamination source. For example, the relevant liquid 85 and the like leaking out from the accommodation chamber 62 adheres to the light condenser 42 or the imaging head 44 of the laser processing apparatus 2, resulting in reduction in functions thereof or adheres to various types of mechanisms to deteriorate them. In view of this, in the spinner unit (coating cleaner unit 16a) according to the present embodiment, to reduce entrainment of the liquid 85 remaining inside the accommodation chamber 62 in association with rotation of the spinner table 46, a separator 86 is provided in the accommodation chamber 62. In the following, a configuration of the separator 86 which reduces entrainment of the liquid 85 and the like due to the air flow will mainly be described.

As illustrated in FIG. 2 and FIG. 3, the separator 86 is disposed below the upper surface (holding surface 46a) of the spinner table 46 in the accommodation chamber 62. In addition, the separator 86 is disposed in the accommodation chamber 62 so as to divide the internal space of the accommodation chamber 62 into an upper space 102a and a lower space 104a communicating with the waste fluid path 68. Also, the separator 86 partially closes between the upper space 102a and the lower space 104a. For example, the separator 86 is disposed around the spinner table 46. The separator 86 is, for example, disposed in the accommodation chamber 62 so as to be fixed on an inner wall of the side wall 64 of the accommodation chamber 62. Alternatively, the separator 86 is, for example, supported by a plurality of columnar support structures not illustrated. An upper end of each of the support structures is fixed to a lower surface 88b of a main body 88 of the separator 86, and a lower end of each of the support structures is fixed to the bottom plate 66 of the accommodation chamber 62. The separator 86 may further alternatively be disposed in the accommodation chamber 62 by other methods. The main body 88 of the separator 86 is formed of, for example, a resin material such as polypropylene, polyvinyl chloride, polystyrene, acrylic resin, or polyethylene terephthalate or a material such as stainless steel. It is to be noted that, however, the material of the main body 88 is not limited to these materials. For example, an upper surface 88a and the lower surface 88b of the main body 88 of the separator 86 are parallel to a horizontal plane and flat, and the main body 88 has an annular plate-like shape.

The separator 86 does not completely close the interior of the accommodation chamber 62. As illustrated in FIG. 2, a plurality of through holes 90 vertically penetrating the main body 88 of the separator 86 are formed in the main body 88 of the separator 86. In FIG. 2, one end of each of the through holes 90 is opened. The liquid 85 dropping outside the spinner table 46 is received by the main body 88 of the separator 86. This received liquid 85 enters any of the through holes 90, flowing down below the separator 86. Specifically, each of the through holes 90 serves as a path through which the liquid 85 advances from the upper space 102a of the accommodation chamber 62 to the lower space 104a thereof. In other words, the coating cleaner unit 16a (spinner unit) has a gap serving as a path through which the liquid 85 advances from the upper space 102a of the accommodation chamber 62 to the lower space 104a thereof in the separator 86. Each of the through holes 90 functions as this gap.

In addition, the through holes 90 may not be formed in the main body 88 of the separator 86. For example, the liquid 85 received by the main body 88 of the separator 86 may pass through a gap 92 between the separator 86 and the side wall 64 or a gap 92 between the separator 86 and the spinner table 46 and flow down. In other words, the coating cleaner unit 16a (spinner unit) has the gaps 92 serving as paths through which the liquid 85 advances from the upper space 102a to the lower space 104a in the periphery of the separator 86.

Even in a case in which such a separator 86 is provided in the accommodation chamber 62, the liquid 85 flows down below the separator 86 from the gap. Specifically, the liquid 85 advances from the upper space 102a side to the lower space 104a side without any hindrance. Hence, the separator 86 does not disturb the discharge of the liquid 85 through the waste fluid path 68 from the accommodation chamber 62. Meanwhile, advancement of air flow generated in association with rotation of the spinner table 46 is disturbed by the separator 86. Part of the air flow advances through the gap such as the through hole 90 from the upper space 102a to the lower space 104a. However, compared with a case in which the separator 86 is not disposed in the accommodation chamber 62, momentum of the air flow advancing to the lower space 104a is greatly reduced. Hence, the air flow is weakened in the lower space 104a of the accommodation chamber 62, thereby preventing the liquid 85 and the like remaining in the lower space 104a from being entrained by the air flow. Further, advancement of the liquid 85 being entrained in the lower space 104a of the accommodation chamber 62 to the upper space 102a is disturbed by the separator 86, so that the liquid 85 passing through the gap and advancing toward the upper space 102a is also extremely decreased in amount.

Here, the number and the size of the through holes (gaps) 90 provided in the main body 88 of the separator 86 will be described in detail. When the number of the through holes 90 becomes larger and the size of each of the through holes 90 becomes larger, advancement of the liquid 85 from the upper space 102a to the lower space 104a becomes smoother, and advancement of the air flow also becomes smoother. Hence, the momentum of the air flow advancing toward the lower space 104a becomes stronger, and the liquid 85 is likely to be entrained in the lower space 104a. Conversely, when the number of the through holes 90 becomes smaller and the size of each of the through holes 90 becomes smaller, the momentum of the air flow advancing from the upper space 102a to the lower space 104a is weakened, and advancement of the liquid 85 received by the separator 86 toward the lower space 104a is likely to be disturbed. Accordingly, entrainment of the liquid 85 remaining on the upper surface 88a and the like of the main body 88 of the separator 86 by the air flow may be problematic.

In view of this, a preferable range of a total area B of the through holes 90 provided in the separator 86 and the gaps 92 provided in the periphery of the separator 86 to a total area A of a cut surface obtained by cutting the internal space of the accommodation chamber 62 along a horizontal plane including the separator 86 will be described. A ratio of the total area B in the total area A is preferably 10% or more and 40% or less, more preferably 20% or more and 30% or less. It is to be noted that, however, an area occupied by the spinner table 46 in the cut surface is not counted in the total area A. Here, the total area A is a sum of an area occupied by the main body 88 of the separator 86 in the cut surface and the total area B. In other words, the total area A is a sum of an area of the upper surface 88a of the main body 88 of the separator 86 and the total area B. In other words, the area of the upper surface 88a of the main body 88 of the separator 86 is preferably 60% or more and 90% or less of the total area A, more preferably 70% or more and 80% or less of the total area A.

Incidentally, in a case in which the upper surface 88a of the main body 88 of the separator 86 is not horizontal but is inclined to the gap or the like, the liquid 85 received by the separator 86 is likely to flow on the upper surface 88a and flow down from the gap. In this case, the liquid 85 is less likely to stay on the upper surface 88a of the main body 88, and accordingly, the ratio of the total area B of the through holes 90 provided in the separator 86 and the gaps 92 provided in the periphery of the separator 86 to the total area A can further be reduced. A modification example of the separator 86 in which the upper surface 88a of the separator 86 is inclined will be described later.

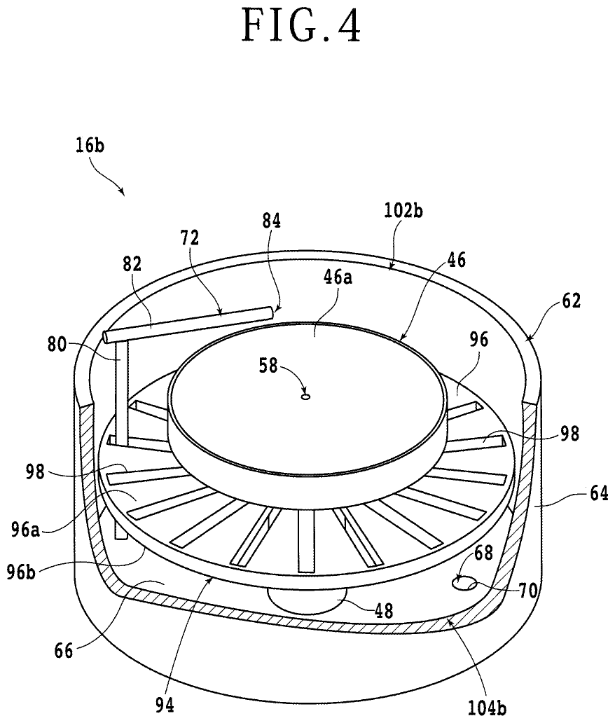

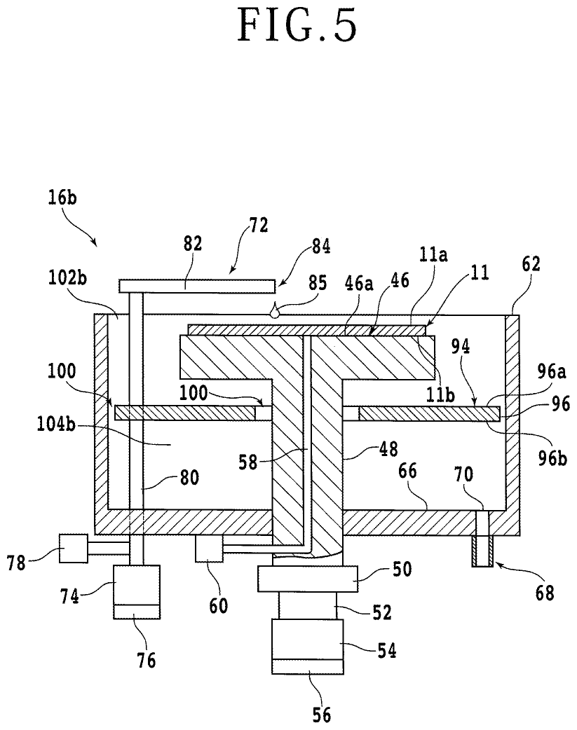

Although the separator 86 disposed in the accommodation chamber 62 outside the spinner table 46 has been described so far, the spinner unit according to the present embodiment is not limited to this. Next, the separator disposed below the spinner table 46 in the accommodation chamber 62 will be described. FIG. 4 is a perspective view schematically illustrating a coating cleaner unit (spinner unit) 16b according to a modification example. FIG. 5 is a cross-sectional view schematically illustrating the coating cleaner unit (spinner unit) 16b according to the modification example of FIG. 4. In the coating cleaner unit 16b below, descriptions of the same configurations as those in the foregoing coating cleaner unit 16a will be omitted. A description of the coating cleaner unit 16a described above can be referenced as a description of the coating cleaner unit 16b, as needed. In the coating cleaner unit 16b, in place of the separator 86, a separator 94 is disposed in the accommodation chamber 62. Since other configurations in the coating cleaner unit 16b are the same as those in the coating cleaner unit 16a, descriptions thereof will not be repeated here.

A position of disposing the separator 94 of the coating cleaner unit 16b and a configuration thereof will be described. As illustrated in FIG. 4 and FIG. 5, the separator 94 is disposed below the spinner table 46 in the accommodation chamber 62. The separator 94 is fixed to the side wall 64. Alternatively, the separator 94 is supported by an unillustrated plurality of columnar structures erected from the bottom plate 66. The separator 94 has a shape and a size surrounding the table rotary axis 48, not the spinner table 46. The separator 94 also does not completely close the interior of the accommodation chamber 62, as in the separator 86 described above. As illustrated in FIG. 4, a plurality of through holes 98 penetrating a main body 96 of the separator 94 from an upper surface 96a thereof to a lower surface 96b thereof are formed in the main body 96 of the separator 94. The through holes 98 serve as paths through which the liquid 85 advances from an upper space 102b to a lower space 104b in the accommodation chamber 62.

In other words, the coating cleaner unit 16b (spinner unit) has gaps serving as paths through which the liquid 85 advances from the upper space 102b to the lower space 104b in the separator 94. Each of the through holes 98 functions as this gap. In addition, the liquid 85 may pass through a gap 100 between the separator 94 and the side wall 64 or a gap 100 between the separator 94 and the table rotary axis 48 and flow down. In other words, the coating cleaner unit 16b (spinner unit) has the gaps 100 serving as paths through which the liquid 85 advances from the upper space 102b to the lower space 104b in the periphery of the separator 94. Even in a case in which the separator 94 is provided in the accommodation chamber 62 in this manner, the liquid 85 flows down from the gaps below the separator 94. Meanwhile, advancement of air flow generated in association with rotation of the spinner table 46 is disturbed by the separator 94, so that entrainment of the liquid 85 and the like remaining in the lower space 104b by the air flow is reduced. Further, the separator 94 prevents the liquid 85 entrained in the lower space 104b of the accommodation chamber 62 from advancing toward the upper space 102b.

Thus, in the spinner unit according to the present embodiment, the separator 86 may be disposed in the periphery of the spinner table 46, and the separator 94 may be disposed in the periphery of the table rotary axis 48. As long as the separator 86 or 94 is disposed at a position lower than the holding surface 46a of the spinner table 46 in the accommodation chamber 62, entrainment of the liquid 85 remaining in the accommodation chamber 62 is reduced.

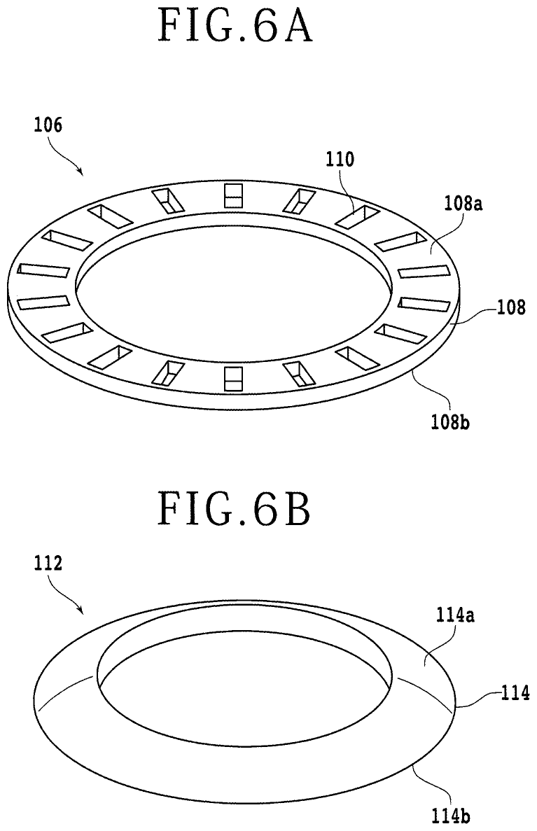

In the following, a modification example of the separator of the spinner unit according to the present embodiment will be described. FIG. 6A is a perspective view schematically illustrating a separator 106 according to the modification example. The separator 106 illustrated in FIG. 6A is also disposed in the accommodation chamber 62 in which the spinner table 46 is accommodated, as in the separators 86 and 94 described above. The separator 106 illustrated in FIG. 6A includes an annular main body 108. The main body 108 has a plurality of through holes 110 formed therein, the through holes 110 penetrating the main body 108 from an upper surface 108a thereof to a lower surface 108b thereof. Each through hole 110 serves as a path through which the liquid 85 flows down. Here, the through hole 110 of the separator 106 is different from the through hole 90 of the separator 86 and is not opened to the side. As such, the through hole 110 formed in the separator 106 may not be opened to the side.

Another modification example of the separator will be described. FIG. 6B is a perspective view schematically illustrating a separator 112 according to another modification example. A main body 114 of the separator 112 illustrated in FIG. 6B does not have a through hole penetrating the main body 114 from an upper surface 114a thereof to a lower surface 114b thereof. The liquid 85 received by the separator 112 flows down in the periphery of the separator 112. For example, the liquid 85 flows down from a gap between the separator 112 and the side wall 64 of the accommodation chamber 62. Here, the upper surface 114a of the main body 114 of the separator 112 illustrated in FIG. 6B is inclined in such a manner as to become lower toward the outside in a diameter direction of the annular main body 114. Consequently, the liquid 85 received by the separator 112 flows down on the inclined upper surface 114a toward the gap between the separator 112 and the side wall 64 of the accommodation chamber 62. As such, since the upper surface 114a of the main body 114 of the separator 112 inclines such that the liquid 85 flows down toward the gap, the liquid 85 is less likely to stay on the separator 112. Hence, entrainment of the liquid 85 remaining on the separator 112 due to air flow is reduced.

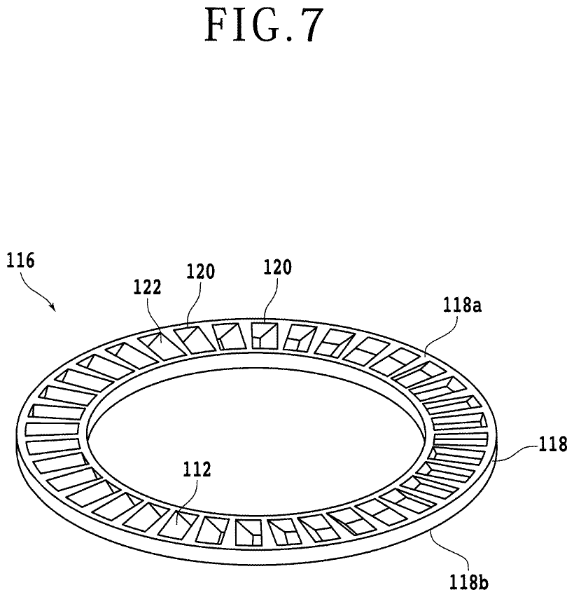

A separator according to still another modification example will be described. FIG. 7 is a perspective view schematically illustrating a separator 116 according to still another modification example. A main body 118 of the separator 116 illustrated in FIG. 7 has a plurality of through holes 120 penetrating the annular main body 118 from an upper surface 118a thereof to a lower surface 118b thereof formed therein. Here, each of the through holes 120 does not extend along a direction vertical to the upper surface 118a. Each of the through holes 120 is formed in the main body 118 along a direction inclined at a predetermined inclination angle from the relevant direction vertical to the upper surface 118a. More specifically, each of the through holes 120 is inclined in such a manner as to be lowered along a circumferential direction of the annular main body 118. The separator 116 will be described from another perspective. The separator 116 has a plurality of plate-like portions 122 each provided between adjacent ones of the through holes 120. Each of the plate-like portions 122 inclines downward along the rotational direction of the spinner table 46. Also, the through hole 120 serving as a gap through which the liquid 85 flows down is positioned between two adjacent ones of the plate-like portions 122.

Here, in the spinner unit, in a state in which the spinner table 46 holding the plate-shaped workpiece 11 is rotated, the plate-shaped workpiece 11 is supplied with the liquid 85. As such, air flow generated in the accommodation chamber 62 in association with the rotation of the spinner table 46 sweeps away the liquid 85 received by the plurality of plate-like portions 122 on an upper surface of each plate-like portion 122 to cause the liquid 85 to flow down to the lower space of the accommodation chamber 62. Thus, making the plate-like portion 122 inclined along a flowing direction of the air flow allows the liquid 85 to flow down with use of the air flow. In this case, the liquid 85 staying in the separator 116 becomes extremely less, so that entrainment of the liquid 85 staying in the separator 116 due to the air flow is further reduced.

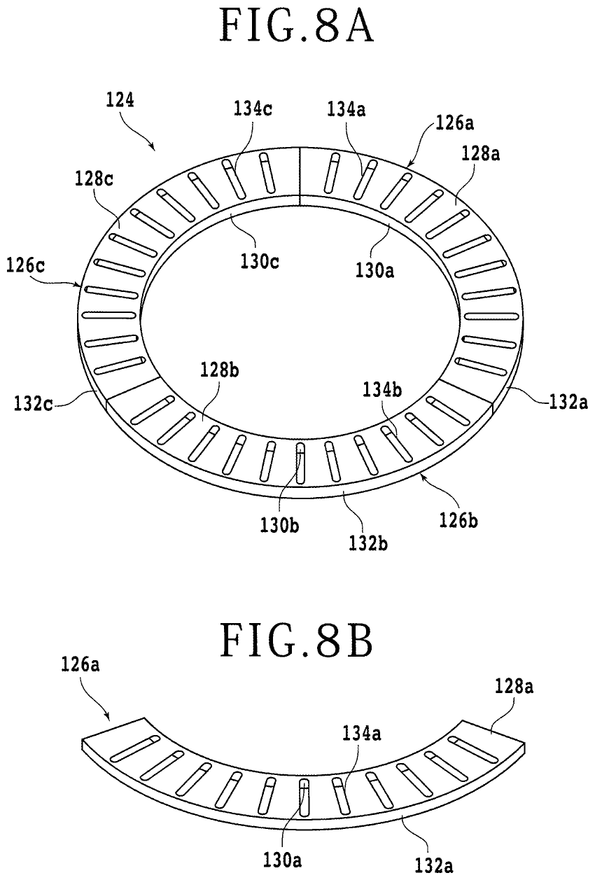

A separator according to yet another modification example will be described. FIG. 8A is a perspective view schematically illustrating a separator 124 according to yet another modification example. A first feature of the separator 124 illustrated in FIG. 8A is that the separator 124 can be divided into three separated parts 126a, 126b, and 126c. In FIG. 8B, a perspective view of one separated part 126a is illustrated. When the separator 124 is dividable, not only carrying the separator 124 but also disposition of the separator 124 into the accommodation chamber 62 become easy. In a case in which the dividable separator 124 is disposed below the spinner table 46 in the accommodation chamber 62, each of the separated parts 126a, 126b, and 126c can pass through a region between the spinner table 46 and the side wall 64 individually. Thus, it is possible to easily dispose the separator 124 in the accommodation chamber 62 without removing the spinner table 46. The separated parts 126a, 126b, and 126c include top plates 128a, 128b, and 128c, respectively, and these top plates 128a, 128b, and 128c have a plurality of through holes 134a, 134b, and 134c formed therein, respectively. The arc-shaped top plates 128a, 128b, and 128c have inner peripheral plates 130a, 130b, and 130c connected on an inner peripheral side thereof, respectively, in such a manner that the inner peripheral plates 130a, 130b, and 130c extend downward. In addition, the top plates 128a, 128b, and 128c have outer peripheral plates 132a, 132b, and 132c connected on an outer peripheral side thereof, respectively, in such a manner that the outer peripheral plates 132a, 132b, and 132c extend downward.

A second feature of the separator 124 illustrated in FIG. 8A is that each of the separated parts 126a, 126b, and 126c can stand on its own on the bottom plate 66 of the accommodation chamber 62 with the inner peripheral plates 130a, 130b, and 130c and the outer peripheral plates 132a, 132b, and 132c as leg portions. In addition, the liquid 85 is able to flow down to a space surrounded by the top plates 128a, 128b, and 128c, the inner peripheral plates 130a, 130b, and 130c, and the outer peripheral plates 132a, 132b, and 132c. Accordingly, when the separator 124 is disposed in the accommodation chamber 62, there is no need to fix the separator 124 to the side wall 64, and the columnar structure supporting the separator 124 is not needed.

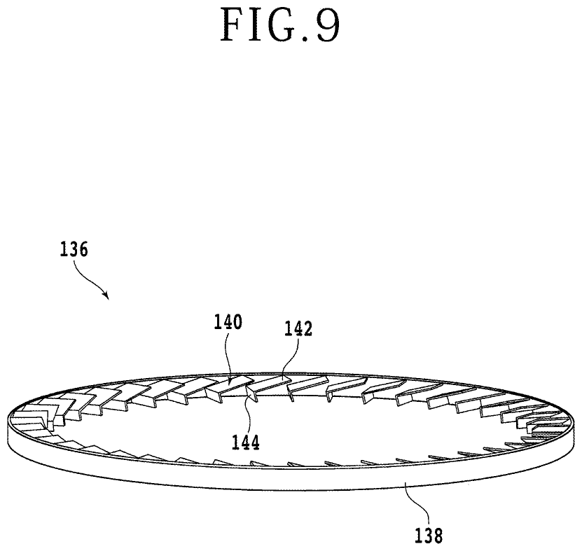

A separator according to a further modification example will be described. FIG. 9 is a perspective view schematically illustrating a separator 136 according to the further modification example. The separator 136 includes a cylindrical side plate 138, and a plurality of plate-like portions 140 fixed at an equal interval on an inner surface of the side plate 138. Also, each of the plate-like portions 140 includes an inclined portion 142 which is inclined along a circumferential direction of the separator 136, and an abutting portion 144 which is bent at the lowermost end of the inclined portion 142. A function of the inclined portion 142 of the plate-like portion 140 and a function of the abutting portion 144 will be described. The inclined portion 142 is inclined in such a manner as to be lower to a moving direction of air flow generated in the accommodation chamber 62 in association with rotation of the spinner table 46, as in the plate-like portion 122 of the separator 116 described in FIG. 7. Hence, the liquid 85 received by the separator 136 flows down on the inclined portion 142 of the plate-like portion 140, while being pushed by the air flow.

Then, part of air flow enters the lower space of the accommodation chamber 62 divided by the separator 136 from a gap of each of the plate-like portions 140, and in this lower space, the remaining liquid 85 is entrained by the air flow. At this time, part of the liquid 85 entrained by the air flow advances in the lower space with the air flow, attempting to go upward toward the upper space from the gap of each of the plate-like portions 140. However, since each of the plate-like portions 140 has the abutting portion 144 and the air flow collides with the abutting portion 144, it is difficult for the air flow to go upward through the gap of each of the plate-like portions 140. In addition, the liquid 85 moving in the lower space along with the air flow also collides with the abutting portion 144, adhering to the abutting portion 144 to eventually drop on the bottom of the accommodation chamber 62. Hence, in the spinner unit including the separator 136 in the accommodation chamber 62, upward movement of the liquid 85 entrained by the air flow to the upper space is strongly disturbed by the effect of the abutting portion 144.

In the spinner unit according to the present embodiment described above, effects of the separator separate the liquid 85 and the gas from each other in the accommodation chamber 62. Then, the liquid 85 advances to the lower space of the accommodation chamber 62 without any hindrance to be discharged from the waste fluid path 68. Meanwhile, momentum of the air flow entering the lower space of the accommodation chamber 62 is weakened due to the effects of the separator, so that entrainment of the liquid 85 in the lower space hardly occurs. Moreover, advancement of the liquid 85 entrained in the lower space to the upper space is disturbed by the effects of the separator. Accordingly, the entrained liquid 85 is less likely to adhere to the plate-shaped workpiece 11 held on the spinner table 46, and the liquid 85 does not scatter outside the spinner unit.

Besides, a structure, a method, and the like according to the above embodiment may be appropriately modified, and various modifications can be implemented without departing from the scope of the object of the present invention. For example, in the embodiment described above, a case in which the coating cleaner unit 16a or 16b as the spinner unit is incorporated in the processing apparatus such as the laser processing apparatus 2 or the like is mainly described. However, the spinner unit according to an aspect of the present invention is not limited to this. The spinner unit according to the aspect of the present invention may be incorporated in a processing apparatus other than the laser processing apparatus 2 and may be independent without being incorporated in the processing apparatus.

In addition, in the embodiment described above, there has been described a case in which the spinner unit is the coating cleaner unit 16a or 16b which supplies the liquid resin as the liquid 85 to the plate-shaped workpiece 11 to allow the water-soluble resin film to be formed on the plate-shaped workpiece 11 and which supplies cleaning water (deionized water) as the liquid to the plate-shaped workpiece 11 to allow the plate-shaped workpiece 11 to be cleaned. However, the spinner unit according to the aspect of the present invention is not limited to the coating cleaner unit 16a or 16b. The spinner unit according to the aspect of the present invention may be a coater unit (spin coater) which supplies the liquid resin as the liquid 85 to the plate-shaped workpiece 11 to form a resin film thereon. In addition, the spinner unit according to the aspect of the present invention may be a spinner cleaning unit which supplies cleaning water (deionized water) as the liquid to the plate-shaped workpiece 11 to clean the plate-shaped workpiece 11. Alternatively, the spinner unit according to the aspect of the present invention may supply the liquid 85 to the plate-shaped workpiece 11 for other purposes. In either case, since the spinner unit according to the aspect of the present invention includes the separator, entrainment of the liquid 85 due to air flow can be reduced.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A spinner unit provided with a spinner table which holds a plate-shaped workpiece and rotates, a liquid supply nozzle which supplies liquid to the plate-shaped workpiece held on the spinner table, an accommodation chamber which accommodates the spinner table, and a waste fluid path which is communicated with the accommodation chamber, the spinner unit comprising:
a separator which is disposed below an upper surface of the spinner table in the accommodation chamber so as to divide the accommodation chamber into an upper space and a lower space, the lower space being communicated with the waste fluid path, and which partially closes between the upper space and the lower space,
wherein the spinner unit has gaps each serving as a path through which the liquid advances from the upper space to the lower space in the separator or in a periphery of the separator.

2. The spinner unit according to claim 1,
wherein the separator has a plurality of through holes constituting the gaps, and causes the received liquid to flow down from the through holes to the lower space of the accommodation chamber.

3. The spinner unit according to claim 1,
wherein an upper surface of the separator is inclined so as to cause the received liquid to flow down toward the gaps.

4. The spinner unit according to claim 1,
wherein the separator includes a plurality of plate-like portions each being inclined downward along a rotational direction of the spinner table,
each of the gaps is positioned between two adjacent ones of the plate-like portions, and
air flow generated by rotation of the spinner table sweeps away the liquid received by the plurality of plate-like portions on an upper surface of each plate-like portion, to cause the liquid to flow down to the lower space of the accommodation chamber.
